(19) United States
(12) Patent Application Publication
(10) Pub. No.: US 2009/0152649 A1
(43) Pub. Date: Jun. 18, 2009

(54) Semiconductor Device of Multi-Finger Type

(76) Inventor: Su Tae Kim, Jinan-gun (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/247,251

(22) Filed: Oct. 8, 2008

(30) Foreign Application Priority Data
Dec. 17, 2007 (KR) 10-2007-0132058

(51) Int. Cl. H01L 47/00

(52) U.S. Cl. 257/409; 257/E47.001

(57) ABSTRACT

Provided is a semiconductor device of a multi-finger type. The semiconductor device comprises an active region, a guard ring, a source electrode, at least one gate electrode, and at least one drain electrode. The active region includes a source region, a drain region, and a channel region. The guard ring surrounds the active region. The source electrode is connected to the guard ring and a bulk region. The source electrode includes electrode bodies disposed on a first side of the active region and a second side of the active region opposite the first side, and fingers connecting the two electrode bodies to branch through the source region. The gate electrode can be provided in plurality as fingers on the channel region. One or more gate electrode fingers can be connected to each other through a set of vias. The drain electrode can be provided in plurality as fingers branching on the drain region.

### CROSS-REFERENCE TO RELATED APPLICATION

The present application claims the benefit under 35 U.S.C. §119 of Korean Patent Application No. 10-2007-0132058, filed Dec. 17, 2007, which is hereby incorporated by reference in its entirety.

### BACKGROUND

Radio frequency (RF) mixed-mode semiconductor devices are emerging for a variety of applications including wireless communication applications. One such device is an RF metal oxide semiconductor field-effect transistor (MOSFET) that uses a multi-finger structure to improve its RF performance through, for example, reducing noise generated by gate resistance.

FIGS. 1 and 2 provide a related art example for an RF mixed mode semiconductor device. FIG. 1 is a plan view of a package substrate 10 having ground signal ground (GSG) electrode structure with a semiconductor device 20 mounted thereon, and FIG. 2 is a plan view illustrating a finger type electrode structure of a semiconductor device 20.

Referring to FIG. 1, the package substrate 10 includes six electrodes. Four of the six electrodes are disposed on an edge portion of the substrate 10 and are used as ground electrodes 11. The other two electrodes, which are located between the ground electrodes 11, are used as signal electrodes 12. The ground electrodes 11 are connected to conductive patterns 13 located at an outer region of the package substrate 10, and the signal electrodes 12 are connected to conductive patterns 14 at an inner region of the package substrate 10. The semiconductor device 20 is mounted on a center of the substrate 10 and electrically connected to the conductive patterns 13 and 14 using four nodes.

Referring to FIG. 2, the semiconductor device 20 includes four electrode bodies disposed around an active region 24. Two oppositely positioned electrode bodies are for source electrodes 21, a third electrode body is for drain electrodes 22, and a fourth electrode body is for gate electrodes 23. The electrodes (source electrodes 21, drain electrodes 22, and gate electrodes 23), in the form of finger shape branches, extend from each of the electrode bodies to the active region 24.

Fingers of the source electrodes 21 and fingers of a drain electrode 22 are alternately disposed between fingers of a gate electrode 23. The source electrodes 21 (and electrode body) may be provided in a different wiring layer than the drain electrodes 22 (and electrode body). For example, the drain electrodes 22 may be provided in a polysilicon layer and the source electrodes 21 may be provided in a first metal layer.

Two of the ground electrodes 11 disposed at a first side of the substrate 10 of FIG. 1 are bonded to the source electrode 21 at a first side of the semiconductor device 20 (see reference 21a of FIG. 2) using the conductive pattern 13 at the first side of the substrate 10, and two of the ground electrodes 11 disposed at a second side of the substrate 10, which is opposite the first side, are bonded to the source electrode 21 at a second side, of the semiconductor device 20, which is opposite the first side, (see reference 21b of FIG. 2) using the conductive pattern 13 at the second side of the substrate 10.

The gate electrode 23 of the semiconductor device 20 is bonded to the signal electrode 12 at a third side of the substrate 10, and the drain electrode 22 of the semiconductor device 20 is bonded to the signal electrode 12 at a fourth side of the substrate 10 opposite the third side.

In order to measure a figure of merit (FOM) of the semiconductor device of a multi-finger type, a test model is often used.

For example, a core model using generic logic having a uni-finger type design may be used as the test model in order to analyze digital circuit characteristics, i.e., DC components. Then a circuit model having an additional external device may be used as the test model in order to analyze analog circuit characteristics, i.e., AC components.

The external device for the test model corresponds to each of the devices in an equivalent circuit, where the analog circuit characteristics according to the multi-finger type are realized using the equivalent circuit.

However, because a drain current per unit width of a finger electrode is degraded, DC data generated by the core model and AC data generated by the equivalent circuit do not conform to actual characteristics of the semiconductor device.

### BRIEF SUMMARY

Embodiments of the present invention provide a semiconductor device of a multi-finger type that can inhibit a drain current from being degraded. According to embodiments, parasitic resistance components of a routing metal can be decreased and/or the number of electrode fingers can be increased compared to related art devices to inhibit the degradation of the drain current.

In one embodiment, a semiconductor device of a multi-finger type comprises: an active region comprising a source region, a drain region, and a channel region; a guard ring surrounding the active region; a source electrode connected to the guard ring and a bulk, the source electrode comprising electrode bodies disposed on a first side and a second side opposite the first side of the active region and a plurality of fingers connecting the two electrode bodies, the plurality of fingers branching over the source region in a direction perpendicular to the longitudinal direction of the two electrode bodies; a gate electrode over the channel region; and a drain electrode over the drain region.

The details of one or more embodiments are set forth in the accompanying drawings and the description below. Other features will be apparent from the description and drawings, and from the claims.

### BRIEF DESCRIPTION OF THE DRAWINGS

FIG. 1 is a view of a substrate having a GSG electrode structure with a semiconductor device mounted thereon.

FIG. 2 is a plan view illustrating a finger type electrode structure of a semiconductor device that can be mounted on the substrate having the GSG electrode structure of FIG. 1.

FIG. 3 is a view of a test model used in a measurement and experiment performed for deducing a structure of a semiconductor device of a multi-finger type according to an embodiment of the present invention.

FIG. 4 is a view illustrating an equivalent circuit of the test model of FIG. 3.

FIG. 5 is a graph illustrating measured verses calculated drain current using embodiments of the test model of FIG. 3 and the equivalent circuit of FIG. 4.

FIGS. 6A and 6B provide a layout view illustrating a semiconductor device of a multi-finger type according to an embodiment of the present invention and an enlarged view of the layout according to an embodiment of the present invention, respectively.

### DETAILED DESCRIPTION

Hereinafter, a semiconductor device of a multi-finger type according to an embodiment will be described in detail with reference to the accompanying drawings.

Embodiments of the subject multi-finger type semiconductor device can be arranged based upon a structure deduced through performing measurements using a test model.

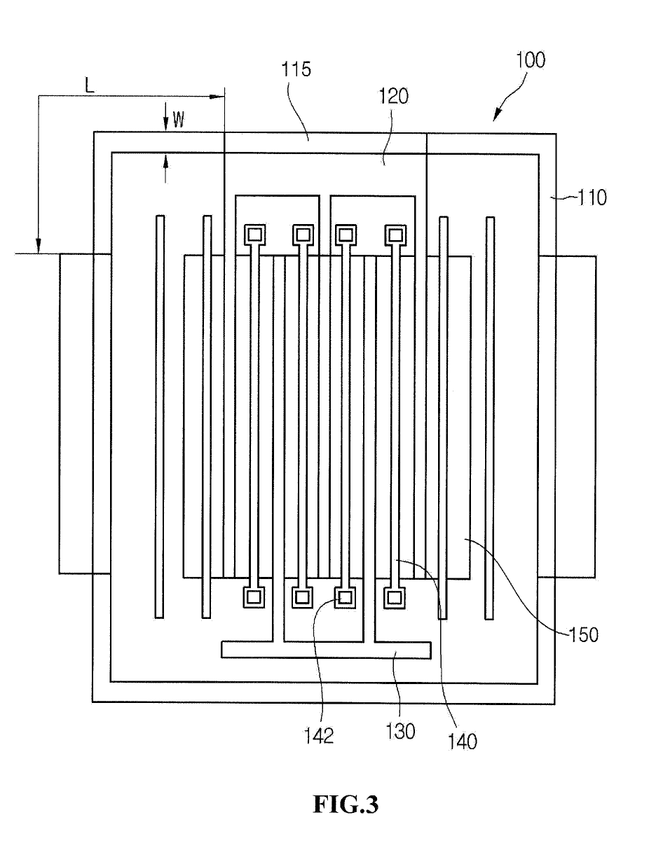

FIG. 3 is a view of a test model 100 used in a measurement and experiment performed for deducing a structure of a semiconductor device of a multi-finger type according to an embodiment.

Referring to FIG. 3, the test model 100 illustrates multi-finger electrodes of the semiconductor device. The test model 100 includes a guard ring 110, a source electrode 120, a drain electrode 130, and a gate electrode with fingers 140.

An active region 150 is defined in a substrate region, and fingers of the source electrode 120, fingers of the drain electrode 130, and fingers 140 of the gate electrode alternatingly cross over the active region. The source electrode 120 is electrically connected to the guard ring 110 and a bulk region (not shown).

The bulk region is a substrate region where the doping concentration is low, but is not the active region having a source region, drain region, and a channel region. Since a bias voltage (bulk effect or body effect) generated on a substrate acts to vary a threshold voltage, the bulk region can be connected to a ground. Hence, the threshold voltage can be stabilized.

In a mixed-mode semiconductor device, noise of a digital circuit has an effect on an analog circuit of the device, thus resulting in poor signal to noise ratio (SNR) of the analog circuit.

In order to reduce such a phenomenon, the guard ring 110 is disposed between the analog circuit and the digital circuit.

The guard ring 110 can be fabricated using an N-well between the analog circuit and the digital circuit, and a highest available bias voltage Vdd can be applied to the guard ring 110. A P+ plug (not shown) for applying a lowest bias voltage GND can be disposed on the substrate neighboring the guard ring 110.

Accordingly, a backward diode having a large potential can be disposed around the guard ring 110 to reduce the noise generated in the digital circuit and obtain good characteristics without the latch-up phenomenon.

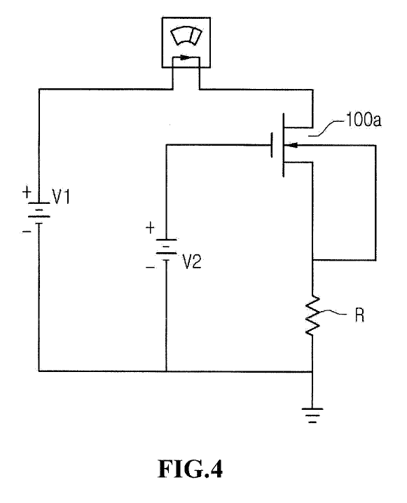

FIG. 4 is a view illustrating an equivalent circuit of the test model 100 of FIG. 3.

Referring to FIG. 4, a first power source V1 is a bias power source applied to the drain electrode 130 of the semiconductor device 100a and a second power source V2 is a bias power source applied to the gate electrode fingers 140 of the semiconductor device 100a on the equivalent circuit. A current measurement device for measuring a drain current is also connected to the equivalent circuit.

A resistor R connected to the source electrode 120 denotes the resistance of a parasitic component. This resistance R reflects the resistance from the guard ring 110, which serves as a routing metal for the drain electrode 130 and the source electrode 120.

The gate electrode is connected to a gate poly (fingers 140) of a lower layer through a metal contact 142. Table 1 illustrates the parasitic resistance value R according to the number of guard rings, a length measurement, and the width of the guard rings.

TABLE 1

| Number | Length (L) (μm) | Width (W) (μm) | Resistance value |
|---|---|---|---|
| of guard rings | of guard ring | of Guard ring | (Ω) |
| 1 | 5.85 | 0.3 | 1.6 |
| 2 | | 0.65 | 0.74 |
| 3 | | 0.98 | 0.49 |
| 1 | 6.75 | 0.3 | 1.85 |
| 2 | | 0.64 | 0.86 |
| 3 | | 0.98 | 0.56 |

As can be seen from the Table 1, the length L, of the guard ring 110 denotes a length of an edge portion between the source electrode 120 and the active region. As the number and width W of the guard ring 110 increase, the resistance value Ω decreases, and the drain current is improved. A resistance of a metal line (see e.g., reference 115) providing the connection of the source electrode 120 and the guard ring 110 acts as the parasitic resistance.

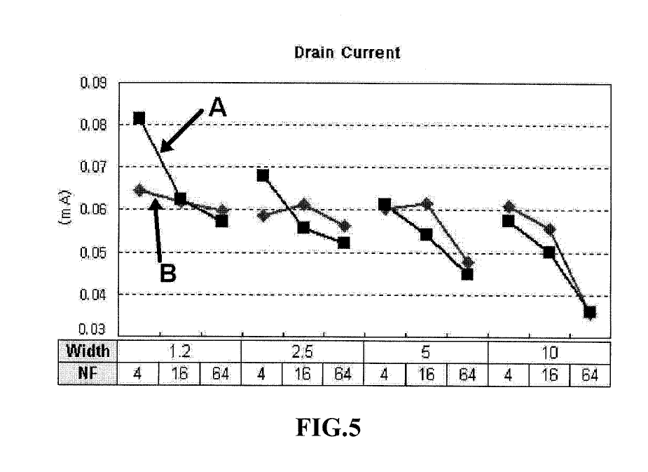

FIG. 5 is a graph illustrating drain current measurements verses modeling values using the test model of FIG. 3 and the equivalent circuit of FIG. 4, respectively.

Referring to FIG. 5, four measurement lines denote measurement values of the drain current when the width W of the guard ring 110 used as the routing metal of the source electrode 120 is set to 1.2 μm, 2.5 μm, 5 μm, and 10 μm, respectively. For each width W, a drain current value is provided with respect to the number of fingers (NF) of the source electrode 120, which is set to 4, 16, and 64 accordingly.

A measurement line “A” denotes data analyzed by the core model and the equivalent circuit, and a measurement line “B” denotes actual measurement data. According to analysis of the data, as the number of the fingers of each of electrodes 120, 130, and 140 increases, the drain current should increase in proportion to increase of the number of the fingers. However, the actual drain current per unit width of the fingers, as with the case of the related art, is degraded.

That is, DC data generated by the core model and AC data generated by the equivalent circuit do not conform to actual characteristics of the semiconductor device.

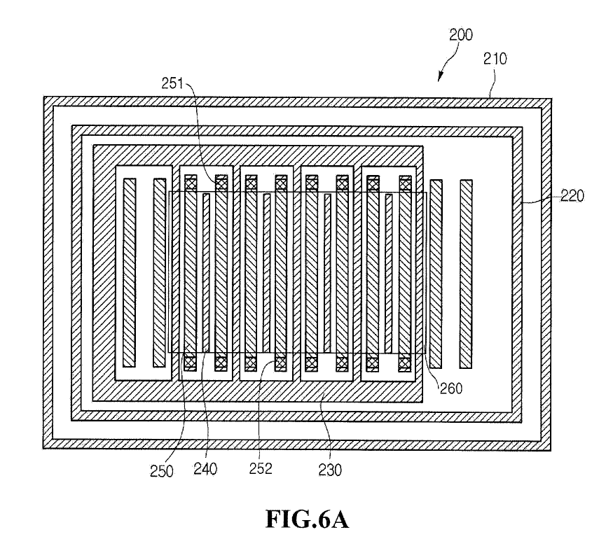

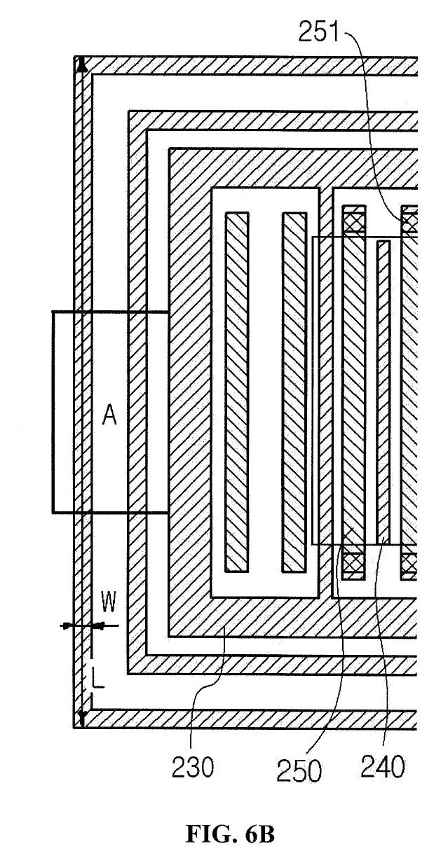

According to the measurement and experiment, the parasitic resistance due to a connection structure between the source electrode 120 and the guard ring 110 has a significant effect on operating characteristics of the semiconductor device of the finger type. Therefore, the connection structures should be taken into consideration. FIGS. 6A and 6B show a schematic view illustrating a semiconductor device 200 of a multi-finger type according to an embodiment.

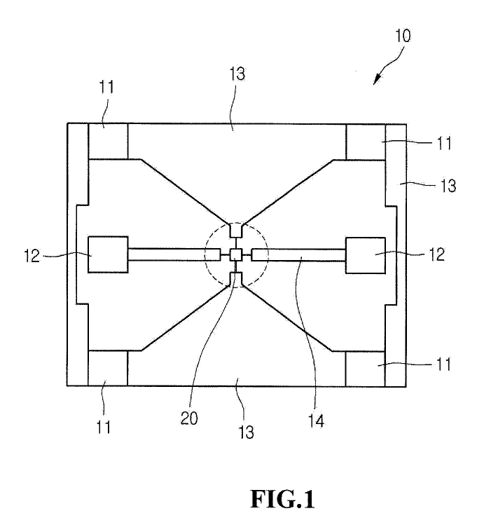

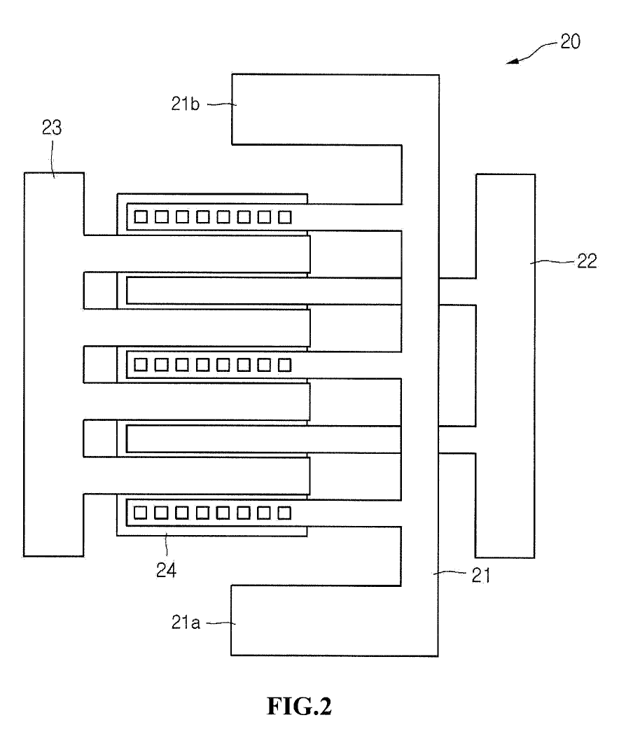

The semiconductor device 200 according to an embodiment can be mounted on the substrate 10 having the GSG electrode structure of FIG. 1 similarly to the semiconductor device described with respect to FIG. 2. Accordingly, repeated descriptions of the substrate having the GSG electrode structure and a mounting structure of the semiconductor device will be omitted herein.

Referring to FIG. 6A, the semiconductor device 200 of the multi-finger type according to an embodiment includes at least one guard ring (e.g., guard rings 210 and 220), a source electrode 230, a gate electrode 250, and a drain electrode 240.

One or more gate electrodes 250 can be provided as a plurality of fingers branching over an active region 260. A metal line (not shown) can connect to one or more of the plurality of fingers through a first set of contacts 251. In a further embodiment, a second metal line (not shown) can be included to connect to one or more of the plurality of fingers through a second set of contacts 252. Each finger can have its own set (251, 252) of contacts. The gate electrodes 250 shown in FIG. 6A as not branching over the active region 260 may function as dummy gate electrodes. Alternatively, these gate electrodes may be omitted and the device area within the guard ring further reduced.

One or more drain electrodes 240 can be provided as a plurality of drain fingers. Although not shown, each drain electrode 240 can have one or more contacts connecting to a signal, ground, or power line. The source electrode 230 can include a plurality of fingers providing a common source. The drain electrode fingers 240 and the fingers of the source electrode 230 can be alternately disposed between the gate electrode fingers 250.

In the semiconductor device of the multi-finger type, the fingers of the source electrode 230 and the drain electrode fingers 240 can be symmetrically disposed about the gate electrode fingers 250. Hence, the electrodes may be selectively used by controlling signals applied to the source electrode 230 and the drain electrode 240.

In some cases, the source electrode 230 may be used as the drain electrode 240, and the drain electrode 240 may be used as the source electrode 230 providing a common-drain structure.

The source electrode 230 is connected to the guard rings 210 and 220 and a bulk region (not shown). The source electrode 230 has a body portion disposed on a first side of the active region and a body portion disposed on a second side of the active region opposite to the first side.

Both body portions of the source electrode 230 are connected by a connection line disposed on a third side of the active region.

Therefore, the body portion of the source electrode 230 branching to the fingers has a “ [symbol] ” shape. Hence, a length of the metal line connected to the guard rings 210 and 220 can be significantly reduced.

The gate electrode 250, the drain electrode 240, and the source electrode 230 can be formed of a metal line such as copper (C) or aluminum (Al). The electrodes 250, 240, and 230 can be respectively disposed on different semiconductor layers. According to certain embodiments, multiple metal layers can be used to provide the electrodes and fingers.

Although two guard rings 210 and 220 are shown in the embodiment illustrated in FIGS. 6A and 6B, the present disclosure is not limited thereto. For example, one, three, or more guard rings may be provided.

The guard rings 210 and 220 surround the source electrode 230, the gate electrode 250, and the drain electrode 240. Thicknesses (W) and lengths (L) of the guard rings 210 and 220 may be adjusted according to the structure in which the source electrode 230 is connected. For example, as shown in FIG. 6B, the connection part of the source electrode 230 can be provided as area “A,” which can be part of the body portion of the source electrode 230.

The semiconductor device 200 of the multi-finger type arranged according to an embodiment can improve the structure of the source electrode 230 to reduce the parasitic resistance components and minimize the degradation of the drain current.

According to embodiments, the parasitic resistance components of the routing metal connecting the source electrode to the guard ring can be reduced, and the degradation of the drain current can be minimized. In one embodiment, this can be accomplished using an equivalent circuit of the device of FIGS. 6A and 6B.

In addition, the DC characteristics, the AC characteristics, and the operation reliability of the semiconductor device of the multi-finger type can be improved.

Accurate simulation results can be obtained before the semiconductor device is fabricated, and the finger structure can be stably designed.

Any reference in this specification to “one embodiment,” “an embodiment,” “exemplary embodiment,” etc., means that a particular feature, structure, or characteristic described in connection with the embodiment is included in at least one embodiment of the disclosure. The appearances of such phrases in various places in the specification are riot necessarily all referring to the same embodiment. Further, when a particular feature, structure, or characteristic is described in connection with any embodiment, it is submitted that it is within the purview of one skilled in the art to effect such feature, structure, or characteristic in connection with others of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device of a multi-finger type comprising:
an active region comprising a source region, a drain region, and a channel region;
a guard ring surrounding the active region;
a source electrode connected to the guard ring and a bulk region, the source electrode comprising:
a first electrode body portion disposed at a first side of the active region and a second electrode body portion disposed at a second side of the active region opposite the first side, and
a plurality of fingers connecting the first electrode body portion to the second electrode body portion and branching over the source region in a direction perpendicular to the longitudinal direction of the first and second electrode body portions;
a gate electrode over the channel region; and
a drain electrode over the drain region.

2. The semiconductor device according to claim 1, wherein the source electrode further comprises a connection line connecting the first electrode body portion to the second electrode body portion on at least one of a left side and a right side thereof.

3. The semiconductor device according to claim 1, wherein the guard ring surrounds the source electrode, the gate electrode, and the drain electrode.

4. The semiconductor device according to claim 3, wherein a thickness and a length of the guard ring are provided according to a structure in which the source electrode is connected.

5. The semiconductor device according to claim 1, further comprising one or more additional guard rings surrounding the guard ring surrounding the active region.

6. The semiconductor device according to claim 1, wherein the gate electrode is provided in plurality as a plurality of gate electrode fingers branching over the channel region, and wherein the drain electrode is provided in plurality as a plurality of drain electrode fingers branching over the drain region.

7. The semiconductor device according to claim 6, wherein the fingers of the source electrode and the drain electrode fingers are alternatingly arranged between adjacent gate electrode fingers.

8. The semiconductor device according to claim 6, wherein one or more gate electrode fingers are connected through a set of vias.
